(19) United States
(12) Patent Application Publication
(10) Pub. No.: US 2010/0265715 A1
(43) Pub. Date: Oct. 21, 2010

(54) Adjustable, Outdoor Light Unit, and Method for Making and Using the Same

(75) Inventors: Nathan B. Winstanley, Lenox, MA (US); Philip A. Cohen, Richmond, MA (US); Brendan M. Walsh, Pittsfield, MA (US); Ashok Alilughatta Sathyanarayana, Pune (IN)

Correspondence Address: CANTOR COLBURN, LLP, 20 Church Street, 22nd Floor, Hartford, CT, 06103, US

(73) Assignees: Sigma Electric Manufacturing Corporation, Garner, NC (US); Winstanley Partners, Lenox, MA (US)

(21) Appl. No.: 12/752,339

(22) Filed: Apr. 1, 2010

Related U.S. Application Data
(60) Provisional application No. 61/169,949, filed on Apr. 16, 2009.

(51) Int. Cl. F21V 17/02; H05K 13/00

(52) U.S. Cl. 362/277; 29/592.1

(57) ABSTRACT

In one embodiment, a light comprises: a body portion, a base, and an electrical power cord connected to the body and capable of establishing electrical communication between the light source and an electricity source. The body portion can comprise a lens, a light source, a reflector, a body connection, and a focusing element. The focusing element can be configured to create relative movement between the light source and the reflector, such that, when in use, a spread of a light beam from the light source can be adjusted. The base comprise can comprise a mounting element and a base connector capable of connecting to the body connection.

### CROSS-REFERENCE TO RELATED CASE

This application claims priority to Provisional Patent Application No. 61/169,949, file Apr. 16, 2009, and incorporated herein in its entirety by reference.

### TECHNICAL FIELD

The present application is directed to lights, and especially to adjustable outdoor light units.

### BACKGROUND

Outdoor light fixtures have been known for many years and include an outdoor spot light that produces a concentrated narrow beam of light used for illumination of a small area, and an outdoor flood light that produces a larger, less concentrated beam of light used for illumination of a larger area. In the past, conventional outdoor lighting fixtures were designed and constructed to provide a desired light distribution for a particular application. For example, a landscaper or homeowner would have to determine the specific beam width required for an application and purchase an outdoor light fixture specifically designed for this application. Some outdoor lights are variable focus, i.e. they can be adjusted by the user for either a narrow beam, (e.g. spot lighting) or a wide beam (e.g. flood lighting).

There continues to be a need to light units for outdoor use.

### SUMMARY

Disclosed herein are adjustable outdoor light units and methods for making and using the same.

In one embodiment, a light comprises: a body portion, a base, and an electrical power cord connected to the body and capable of establishing electrical communication between the light source and an electricity source. The body portion comprises of a lens, a light source, a reflector, a body connection, and a focusing element. The focusing element can be configured to create relative movement between the light source and the reflector, such that, when in use, a spread of a light beam from the light source can be adjusted. The base comprises a mounting element, swivel connection, and a base connector capable of connecting to the body connection.

In one embodiment, a method for providing light can comprise: connecting an electrical plug of the light unit to an electricity source and moving the switch to the on position so that electricity is enabled to the light source.

The above described and other features are exemplified by the following figures and detailed description.

### BRIEF DESCRIPTION OF THE DRAWINGS

Refer now to the figures, which are meant to be exemplary and not limiting, and wherein like elements are numbered alike.

FIG. 1 is a frontal perspective view of an embodiment of an outdoor light unit including an adjustable light, a ground fault current interrupter, power cord, and light body.

FIG. 2 is a view of the back portion of the light body of FIG. 1.

FIG. 3 is an expanded, schematic of the light unit of FIG. 1.

FIG. 4 is a side view of one embodiment of a light unit comprising a mounting bracket that can optionally also hold the GFCI.

FIG. 5 is a side view of one embodiment of a mounting element having a ball and threads.

FIG. 6 is a perspective side view of one embodiment of another mounting element having a ball-like element (e.g. partial sphere) and a deck.

FIG. 7 is a perspective view of one embodiment of a light unit with a mounting element having a belt.

FIG. 8 is a perspective view of one embodiment of a light unit with a mounting element having a clamp.

### DESCRIPTION

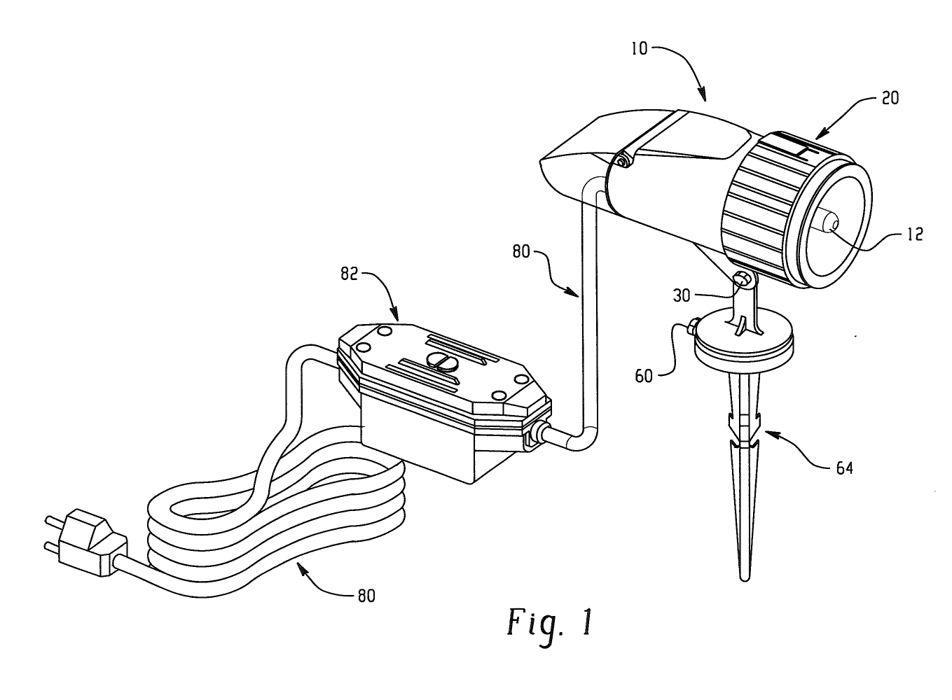

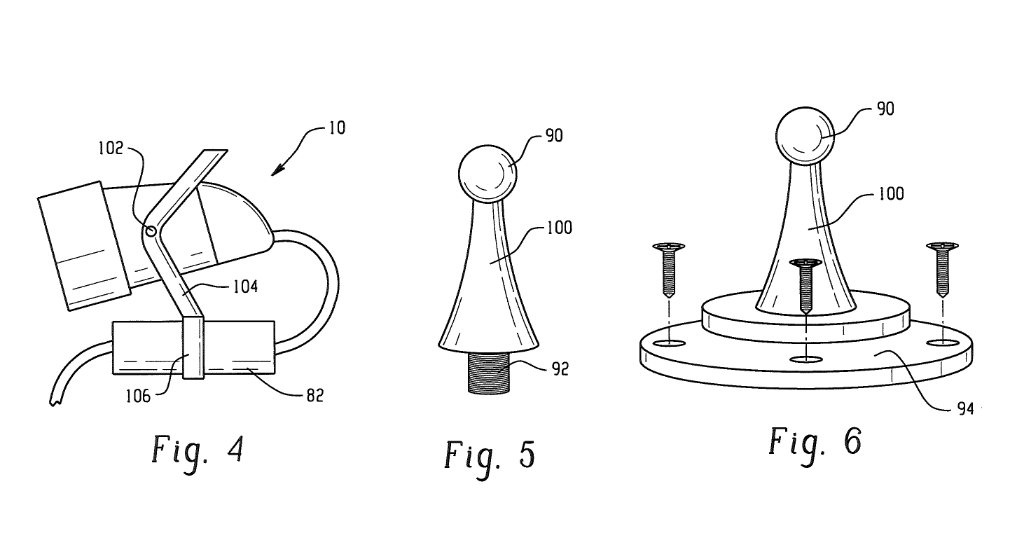

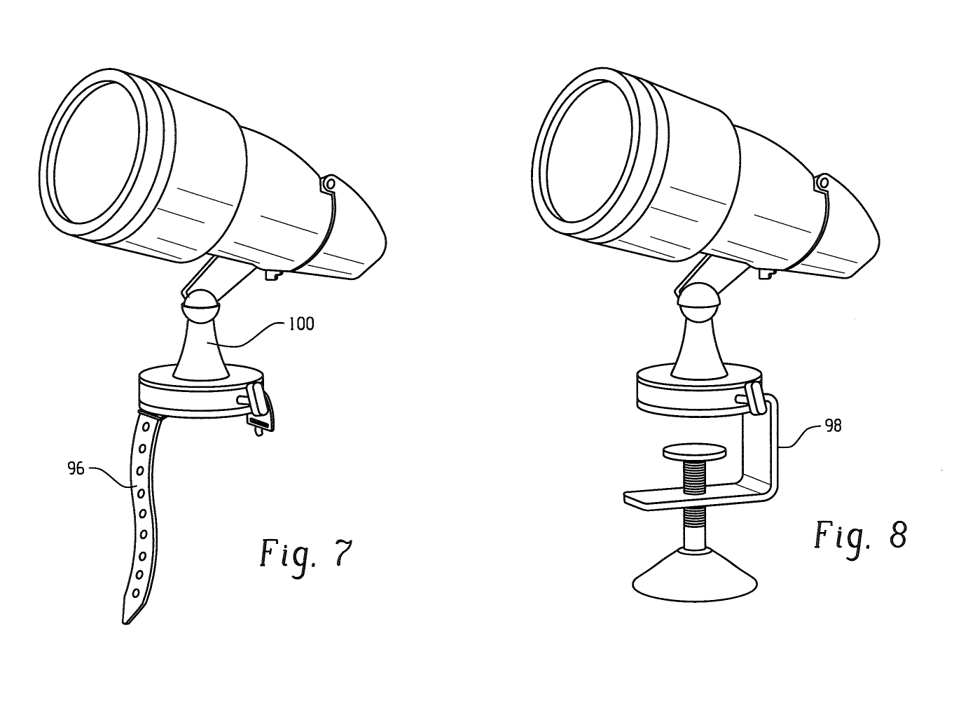

The adjustable outdoor light unit (e.g., luminaire) can have a focusable spot-to-flood feature. This light can be portable yet have an in-line ground fault current interrupter (GFCI) on the cord. The light comprises light source(s) (e.g., halogen bulb(s), light emitting diode(s) (LED), and so forth), and reflector(s). Relative movement between the light source and the reflector is effected to attain the desired focusable feature. In some embodiments, the light can optionally comprise one or more of the following: a body portion, a body knob, a base, and an electrical power cord. The body portion can comprise one or more of a body, a lens cover (optionally forming a shroud), a protective lens, light source (e.g., bulb, diode,), reflector, focusing element, an electrical plug receptacle (e.g., for insertion of standard electrical plugs based upon either the country and/or the voltage), a switch, a movable cover (e.g., for covering the switch and/or electrical plug receptacle), and a body connection. The base (e.g., for mounting the light to the ground) can comprise one or more of a mounting element (e.g., a stake(s) (e.g., see FIG. 1), bracket(s) (e.g., see FIG. 4), threaded attachment(s) (e.g., see FIG. 5), deck mount(s) (e.g., see FIG. 6), belt(s) (e.g., see FIG. 7), clamp(s) (e.g., see FIG. 8), and so forth, as well as combinations comprising at least one of these mounting elements), a swivel connection, a stake knob and a base connecter. The electrical power cord (e.g., flexible electrical cord) is connected to the body, and can comprise a ground fault circuit interrupt (GFCI) and a plug(s). The plug and plug receptacle can be used to connect a plurality of lights in series, with at least one of the plugs connected to an electricity source. Optionally, the base and body can be connected with a ball joint such that the body can move multiple directions without adjustment of both a body knob and a stake knob. The stake can have spike(s), divot(s), and so forth, so as to enable secure attachment to the ground.

The light comprises a body knob that enables the light body (and hence the light beam produced by the light source) to be oriented in various positions (e.g., in an azimuthal plane) by loosening the body knob and adjusting the angle of the body. The light may also be adjustable along the transverse plane by loosening the stake knob and swiveling the body left and/or right.

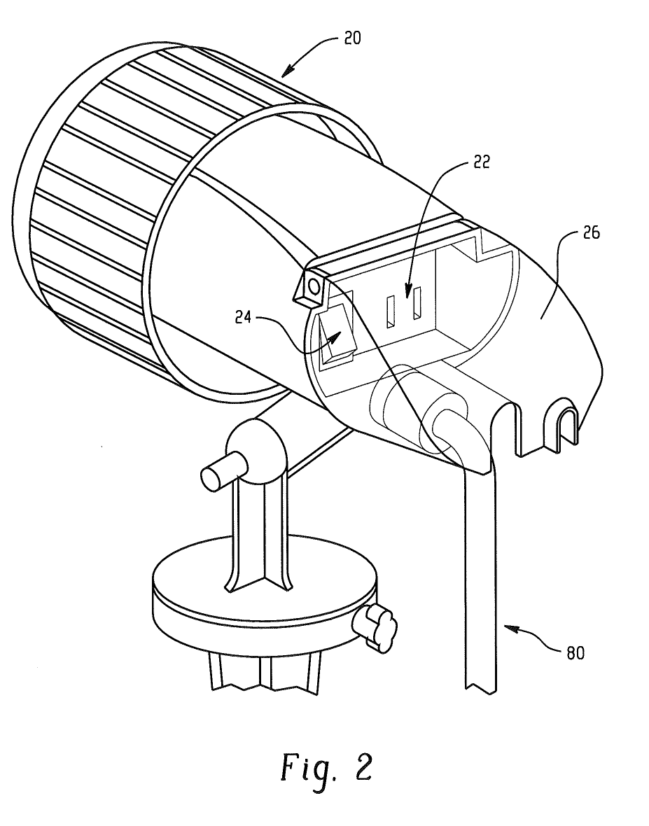

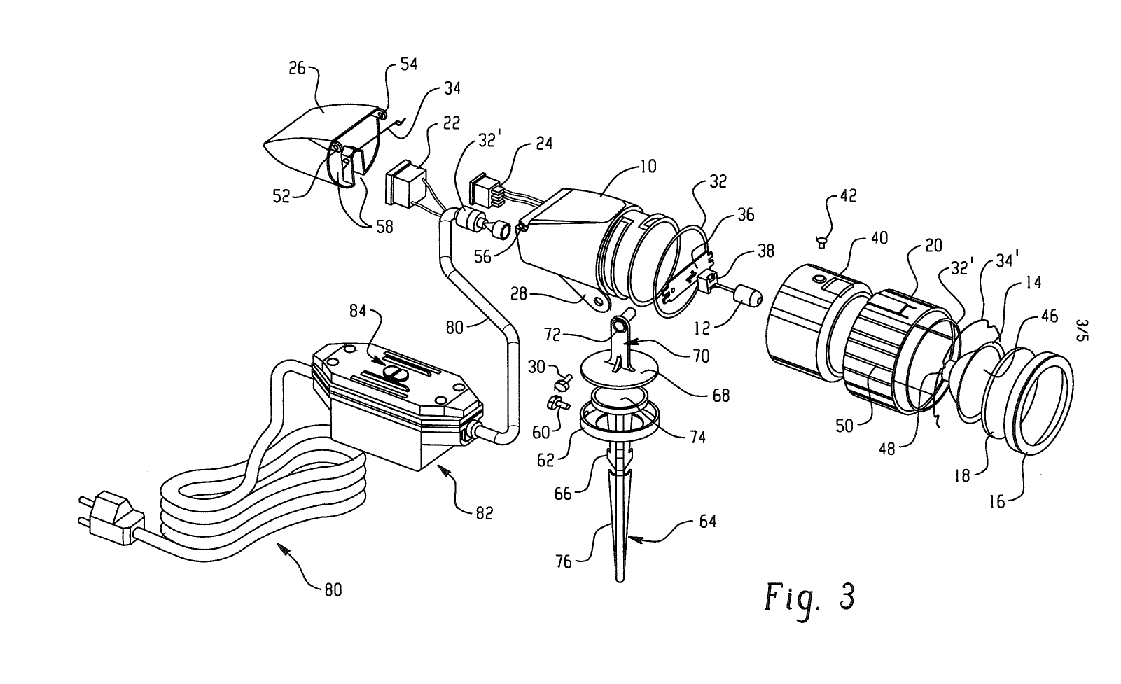

As illustrated in the figures (FIGS. 1-3), the light has a body (10). At one end of the body (10) is a lens cover (16) surrounding and retaining a lens (18) that is adjacent to a parabolic reflector (14). Optionally, the lens cover (16) can form a shroud around the lens (18), projecting outward from the body (10), away from the lens (18). The surface of the lens cover (16) can be straight or angled, and can be substantially flush with the lens (18), or can extend up to several inches from the body (10) (e.g., can extend 0.5 cm to 8 cm from the body (10), wherein, in some embodiments, an upper portion of the lens cover (16) can extend 2.5 cm to 5 cm from the body (10), while the lower portion of the lens cover (16) can extend 1 cm to 2.5 cm, and wherein the lower portion extends greater than or equal to 0.5 cm less than the upper portion).

The reflector (14) fits into reflector housing (40) that has an opening for a focusing pin (42). A focusing element (20) is disposed around the reflector (14) and reflector housing (40), and in operable communication with the focusing pin (42). Between any of the various elements (the lens cover (16), lens (18), reflector (14), and reflector housing (40)), can be a seal (e.g., gasket, O-ring, and/or the like). Disposed into the reflector (14) through opening (48) is a light source (e.g., light bulb) (12), with the light source (12) connecting via electrical connectors (e.g., a socket (38), a partition plate (36), and electrical wiring) to the electrical cord (80). Also disposed on the body is a switch (24) configured so as to enable (e.g., complete) and interrupt (e.g., break) electrical communication (i.e., connection) from the electrical power cord (80) to the light source (12).

When assembled, the lens cover (16) is disposed around the lens (18), located in front of the reflector (14). In order to enable light source replacement, the lens cover can be removably attached to the body (10). For example, the body (10) and lens cover (16) can have complementary threads, can snap together, have interlocking protrusion(s) and opening(s), and the like.

The light source (12) extends into the reflector (14) through an opening (48) in the reflector (14) at an end opposite the lens (18). Optionally, the light source (12) can be a single or an array of LEDs, and the reflector can be designed to receive and direct the light from the array.

The reflector (14) is located in the body (10) in the reflector housing (40) with a focusing element (20) disposed around the reflector (14), reflector housing (40), and light source (12). The reflector (14) is parabolic so as to direct the light beam as desired. The reflector (14) comprises a visible light reflective material and/or a visible light reflective coating on an inner surface (46); e.g., a mirrored surface. For example, the reflector (14) can comprise an anodized aluminum material.

Focusing element (20) is in operable communication with the reflector (14) and/or light source (12) so as to be configured to create relative movement between the reflector (14) and light source (12), thereby enabling adjustment of the light beam. For example, rotation of focusing element (20) can exert pressure on focusing pin (42) and hence reflector (14) so as to move the reflector (14) toward the lens (18), while the light source (12) remains in a fixed position. The change in position of the reflector (14) with respect to the light source (12) changes the focus of the light source (12) with respect to the parabola of the reflector (14), thereby changing the dispersion (e.g., adjusting the spread such as between collimated beam and divergent beam) of the light beam emanating from the light source (12) through the lens (18). It is also possible to dispose the focusing element (20) in operable communication with the light source (12) such that the reflector (14) is retained in a fixed position and the light source (12) is moved, relative to the parabola of the reflector (14), upon the turning of the focusing element (20), thereby adjusting the spread of the light beam. It is noted that a turnable focusing element (20) is illustrated. However, other focusing elements are also contemplated, such as a slide mechanism.

The focusing element (20) can have a design so as to enable facile gripping and turning. For example, ridges and/or valleys (50) can be disposed around the focusing element (20). Although the focusing element (20) can be formed from plastic, metal, and/or rubber, facile gripping and adjusting of the light beam can be attained with a rubber and/or plastic focusing element (20) which can optionally have a roughened surface alone, or in combination with, the ridges and/or valleys.

The other end of the body (10) receives the power cord (80) that is in operable communication (e.g., configured to transfer electricity from a power source) with the switch (24) and the receptacle(s) (22). As noted above, the switch (24) can enable/interrupt electricity flow from the power cord (80) to the light source (12) and/or to the receptacle (22). The power cord (80) can comprise an electric plug, e.g. a three contact plug comprising a live contact (also known as the active contact), neutral contact (also known as the identified conductor), and a ground.

The receptacle (22) is configured to receive an electrical plug (e.g., a three contact plug comprising a ground), for example, an electrical plug of another light (e.g., the lights can be arranged in series using the power cord and receptacle (22)). Additionally, if the switch (24) controls the power to the receptacle (22), turning off the switch (22) of the first light in the series will turn off all of the lights, rendering facile use of the lights.

Located over the switch (24) and receptacle (22) is the cover (26). The cover (26) can provide protection of the switch (24) and receptacle (22) from the weather (e.g., rain, hail, and so forth). The cover (26) can have an engagement for connecting the cover (26) to the body (10) in a moveable (e.g., rotatable) manner. For example, the cover (26) can have an extension (52) with an opening (54) for engaging a protrusion (56) on the body (10) such that the protrusion (56) is disposed in the opening (54) such that the cover (26) can rotate vertically, allowing access to the switch (24) and receptacle (22). The cover (26) also has cord passages (58) through which the power cord (80) connects to the body (10), and through which another cord can pass to enable a plug to engage the electrical plug receptacle (22).

Located along the power cord (80) can be an electric circuit protection device capable of ceasing electrical flow from a power source (not shown) to the light when a fault is detected. Possible electric circuit protection devices include a ground fault circuit interrupt (GFCI) (82), a ground-fault equipment protector (GFEPs), an arc fault circuit interrupter (AFCIs), and so forth. Desirably, the GFCI (82) includes an easily test/reset switch, such as a push button (84).

Extending from the lower portion of the body (10) can be a body connection (28) that is designed to connect with a base connector (70) of the stake. The body connection (28) and base connector (70) are configured to enable adjustment of the direction of the light beam along a vertical plane. For example, the body connection (28) and base connector (70) can have complementary teeth (72), or other mechanism that enables vertical movement of the body (10) in relation to the stake. The body connection (28) and base connector (70) are retained together and retained in a desired position with the body knob (30).

The base connector (70) is located on a surface of a base plate (68). The base plate (68) can connect to the stake bottom (64) with a lock ring (62) and a stake knob (60). Similar to the body connection (28) and base connector (70), the base plate (68) and stake bottom (64) are configured so that the body (10) is adjustable with respect to the stake, in the horizontal direction. For example, the lock ring (62) slidably receives the base plate (68) with the stake knob (60), when sufficiently (e.g., tightly) engaged with the lock ring (62) capable of inhibiting the horizontal movement of the body (10).

The stake bottom (64) comprises a platform (74) that slidably contacts the base plate (68), and is disposed within the lock ring (62). Extending from the platform (74) is a picket (76) with spike(s) (66) that allow securement of the light to the ground.

In some embodiments, the body connection can be configured to mate with a mounting element. For example, the body connection can be a socket configured to receive a ball (90) to form a ball and socket joint, or the body connection can be the ball configured to mate with the socket of the base portion (e.g., see FIGS. 5-8). The mounting element can further comprise a treaded portion (92), a deck (94), a belt (96), and/or a clamp (98). For example, the ball can be connected to an arm (100) that further connects to a deck (94) for mounting on a surface (e.g., wall, floor, railing, tree, fence, post, etc.), either directly and/or via a fastener (e.g., hook, clasp, holder, snap, etc.).

In some embodiments, the body connection can be on the side of the light unit so as to attach to a bracket or the like. Referring to FIG. 4, the body connection can be an attachment (102) (e.g., opening (e.g., threaded opening), threaded extension, snap-connection, or the like), that is on the side of the light body (10), to connect the light body (10) to a bracket (104). The mounting element (e.g., the bracket 104) can comprise a GFCI holder (e.g., holding area 106). In some embodiments, the light unit can comprise a variety of the mounting elements

The light also comprises various gaskets (32,32′) (e.g., o-ring(s), washer(s), and so forth), spring(s) (34,34′), connectors (e.g., rivot(s), screws, and so forth), and so forth, which may or may not be illustrated in the figures. Sufficient gaskets, O-rings, and so forth are employed to attain a weatherproof light, and, in particular, weatherproof body.

The materials of the light are chosen to attain the desired structural integrity, conductivity, weather resistance, longevity, insulation, and/or aesthetic appeal. For example, the body (10), lens cover (16), reflector housing (40), cover (26), body connection (28), base connector (70), base plate (68), lock ring (62), and/or stake bottom (64), can, individually, be formed from metal and/or plastic, e.g., die-cast aluminum, galvanized material, stainless steel, and so forth. Generally, metals are used for the body (10), body connection (28), base connector (70), base plate (68), lock ring (62), body knob (30), stake knob (60), and stake bottom (64), for structural integrity, weatherability, and longevity. The lens (18) can comprise any optically transparent material such as glass, optical plastic, and so forth. The receptacle (22) is generally formed of plastic or other dielectric material.

The light unit can comprise a body portion, base, and an electrical power cord. The body portion comprising body, a lens cover, a lens, a light source, a reflector, a body connection, and a focusing element. The focusing element can be configured to create relative movement between the light source and the reflector, such that, when in use, a spread of a light beam from the light source can be adjusted. The base can comprise a stake and a base connector capable of connecting to the body connection. In some of the embodiments, the base can also comprise a swivel connection, e.g., that enables the body to be moved along a horizontal plane. The electrical power cord is connected to the body and is capable of establishing electrical communication between the light source and an electricity source. In one or more of the embodiments, the focusing element is turnable, and, when the focusing element is turned the reflector moves with respect to the light source which is fixed. In one or more of the embodiments the swivel connection is configured to move the body in the horizontal plane and the body connection is configured to move the body in the azimuthal plane. In one or more of the embodiments the light unit further comprises a body knob that allows an adjustable connection between the body connector and the base connection. In one or more of the embodiments the focusing element can be disposed around the reflector and a reflector housing; and the reflector housing can have a focusing pin disposed therethrough in operable communication with both the reflector and the focusing element. In one or more of the embodiments the light unit further comprises a ground fault circuit interrupt located along the electrical power cord between the light body and a plug. In one or more of the embodiments the body further comprises an electric plug receptacle in operable communication with the electrical power cord; a switch configured to enable and interrupt the flow of electricity (e.g., to complete and break an electrical circuit path) from the electrical power cord to the light source and/or configured to enable and interrupt the flow of electricity from the electrical power cord to the electric plug receptacle.

In one or more embodiments, the light unit can produce colored light (e.g., blue, green, red, etc.; the light that exits the unit is other than white light), and/or can be changed from one color to another and/or to white. The colored light can be attained by having one or more colored disk(s) that can be disposed in front of the light source such that, when in use, the light beam travels through the colored disk. The disk can optionally be movable relative to the light source so as to enable the changing of the desired color. In some embodiments, the disk is motorized to as to shift automatically between the colors at a predetermined interval or continually. In other embodiments, the light source comprises LEDs, e.g., blue LED(s), red LED(s), and/or green LED(s).

In use the light unit can be connected to an electricity source (e.g., the power grid), via the plug and electrical power cord. The switch can then be moved to the on position so as to enable the flow of electricity to the light source and thereby, the production of a light beam. The focusing element can be adjusted (e.g., turned), to change the spread of the light beam (e.g., to and/or from a spot light). Optionally, a plurality of light units can be connected together in series by inserting the electrical plug of one light unit into the electrical plug receptacle of a subsequent or prior light unit. As such, if the switch controls the flow of electricity to the electrical plug receptacle, the switch of one light unit can be used to control the flow of electricity to all subsequent light units.

In another embodiment, the electricity flow can be in parallel, such that the switch of each light unit can be configured to only control that light unit such that the various light units can be individually on or off. For example, an electrical plug of a light unit can be connected to an electricity source. The switch can be moved to the on position so that electricity is enabled to the light source. If the light unit is ganged with other light unit(s) (e.g., connected to other light units via the electrical power cord and electrical receptacle, then light can be provided by or more of the light units while other of the light units can be off (i.e., provide no light).

In an embodiment, the light unit can comprise: a body portion, a base, and an electrical power cord. The body portion can comprise a body, lens(es), light source(s), reflector(s), body connection(s), and focusing element(s) configured to create relative movement between the light source(s) and the reflector(s), such that, when in use, a spread of a light beam from the light source(s) can be adjusted. The base can comprise mounting element(s) and base connector(s) capable of connecting to the body connection. The electrical power cord is connected to the body and capable of establishing electrical communication between the light source and an electricity source.

In the various embodiments: (i) the focusing element(s) are turnable, and wherein, when the focusing element is turned the reflector(s) move with respect to the light source(s) which can be fixed; (ii) further comprise swivel connection(s) configured (e.g., designed) to move the body in the horizontal plane and/or wherein the body connection is configured to move the body in the azimuthal plane; (iii) further comprising a body knob that allows an adjustable connection between the body connector and the base connection; (iv) the focusing element(s) can be disposed around the reflector and/or a reflector housing; (v) the reflector housing can have a focusing pin disposed therethrough in operable communication with both the reflector and the focusing element; (vi) further comprising a ground fault circuit interrupt along the electrical power cord between the light body and a plug; (vii) the body can further comprise electric plug receptacle(s) in operable communication with the electrical power cord; (viii) the electricity source can be the electric plug receptacle of another light unit; (ix) when multiple light units are connected together, each light unit can be individually on or off, irrespective of the state of another light unit(s); (x) the body can further comprise switch(es) configured to enable and/or interrupt the flow of electricity from the electrical power cord to the light source(s); (xi) the switch(es) can be configured to enable and interrupt the flow of electricity from the electrical power cord to the electric plug receptacle; (xii) the mounting element can be a stake; (xiii) the light unit(s) can, individually (of each other), produce colored light and/or white light; (xiv) multiple light units (e.g., greater than or equal to 3, specifically, greater than or equal to 5, and more specifically, greater than or equal to 7) can be gangable, wherein the light units can be connected in series or can be connected in parallel, or some of the units can be connected in series while other of the light units can be connected in parallel; (xv) further comprises electrical plug receptacle(s) for connecting the light unit in electrical series with another device (e.g., another light unit); (xvi) further comprises electrical plug receptacle(s) for connecting the light unit in electrical parallel with another device (e.g., another light unit); (xvii) the mounting element can comprise stake(s), bracket(s), threaded attachment(s), deck mount(s), belt(s), clamp(s), as well as combinations comprising at least one of these mounting elements.

The light disclosed herein is an outdoor light that can be focused as desired, and has an electric circuit protection device in-line in the light's power cord. The light can be disposed in series with several of these lights, yet enables facile installation and removal, and can be attached to a power source; e.g., does not require a battery for power (e.g., is totally free of batteries). Alternatively, the light has batteries solely as a back-up power source such that the battery only provides power to the light when the light switch is on and the power from the power cord fails.

The terms “first,” “second,” and so forth, herein do not denote any order, quantity, or importance, but rather are used to distinguish one element from another, and the terms “a” and “an” herein do not denote a limitation of quantity, but rather denote the presence of at least one of the referenced item. The suffix “(s)” as used herein is intended to include both the singular and the plural of the term that it modifies, thereby including one or more of that term (e.g., the plug(s) includes one or more plugs). Reference throughout the specification to “one embodiment”, “another embodiment”, “an embodiment”, “some embodiments” and so forth, means that a particular element (e.g., feature, structure, and/or characteristic) described in connection with the embodiment is included in at least one embodiment described herein, and can or can not be present in other embodiments. In addition, it is to be understood that the described elements can be combined in any suitable manner in the various embodiments.

What is claimed is:

1. A light unit, comprising:
a body portion comprising body, a lens, a light source, a reflector, a body connection, and a focusing element configured to create relative movement between the light source and the reflector, such that, when in use, a spread of a light beam from the light source can be adjusted;
a base comprising a mounting element and a base connector capable of connecting to the body connection; and
an electrical power cord connected to the body and capable of establishing electrical communication between the light source and an electricity source.

2. The light unit of claim 1, wherein the focusing element is turnable, and wherein, when the focusing element is turned the reflector moves with respect to the light source which is fixed.

3. The light unit of claim 1, further comprising a swivel connection configured to move the body in the horizontal plane and wherein the body connection is configured to move the body in the azimuthal plane.

4. The light unit of claim 1, further comprising a body knob that allows an adjustable connection between the body connector and the base connection.

5. The light unit of claim 1, wherein the focusing element is disposed around the reflector and a reflector housing; and wherein the reflector housing has a focusing pin disposed therethrough in operable communication with both the reflector and the focusing element.

6. The light unit of claim 1, further comprising a ground fault circuit interrupt along the electrical power cord between the light body and a plug.

7. The light unit of claim 1, wherein the body further comprises an electric plug receptacle in operable communication with the electrical power cord.

8. The light unit of claim 1, wherein the electricity source can be the electric plug receptacle of another light unit, and wherein, when multiple light units are connected together with the electrical power cord and electric plug receptacle, each light unit can be individually on or off, irrespective of the state of another light unit.

9. The light unit of claim 1, wherein the body further comprises a switch configured to enable and interrupt the flow of electricity from the electrical power cord to the light source.

10. The light unit of claim 9, wherein the switch is configured to enable and interrupt the flow of electricity from the electrical power cord to the electric plug receptacle.

11. The light unit of claim 1, wherein the mounting element is selected from the group consisting of a stake, a bracket, a threaded attachment, a deck mount, a belt, a clamp, and a combination comprising at least one of these mounting elements.

12. A method for providing light, comprising:
connecting an electrical plug of a light unit to an electricity source, wherein the light unit comprises
a body portion comprising body, a lens, a light source, a reflector, a body connection, a switch, and a focusing element configured to create relative movement between the light source and the reflector, such that, when in use, a spread of a light beam from the light source can be adjusted;
a base comprising a mounting element and a base connector capable of connecting to the body connection; and
an electrical power cord connected to the body and capable of establishing electrical communication between the light source and the electricity source, wherein the switch is configured to enable and interrupt the flow of electricity from the electrical power cord to the light source; and
moving the switch to the on position so that electricity is enabled to the light source.

13. The method of claim 12, further comprising plugging a second electrical power cord of another light unit into an electric plug receptacle of the light unit, wherein the electric plug receptacle is in operable communication with the electrical power cord.

14. The method of claim 13, further comprising, providing light with one of the light unit and the another light unit, while the other of the light unit and the another light unit is off.

15. A lighting system, comprising:
a first light unit and a second light unit, wherein the first light unit and the second light unit comprise
a body portion comprising body, a lens, a light source, a reflector, a body connection, an electric plug receptacle in operable communication with an electrical power cord, and a focusing element configured to create relative movement between the light source and the reflector, such that, when in use, a spread of a light beam from the light source can be adjusted;
a base comprising a mounting element and a base connector capable of connecting to the body connection; and
the electrical power cord connected to the body and capable of establishing electrical communication between the light source and an electricity source;
wherein the first light unit electrical power cord is plugged into the second light unit electric plug receptacle, and wherein the first light unit and the second light unit can be individually on or off, distinct of the other of the first light unit and the second light unit.
